(19) United States
(12) Patent Application Publication
(10) Pub. No.: US 2008/0121880 A1
(43) Pub. Date: May 29, 2008

(54) METHOD OF MEASURING THICKNESS OF LAYER IN IMAGE SENSOR AND PATTERN FOR THE SAME

(76) Inventor: Jeong-Su Park, Incheon (KR)

Correspondence Address: SHERR & NOURSE, PLLC, 620 HERNDON PARKWAY, SUITE 200, HERNDON, VA, 20170, US

(21) Appl. No.: 11/935,233

(22) Filed: Nov. 5, 2007

(30) Foreign Application Priority Data
Nov. 27, 2006 (KR) 10-2006-0117374

(51) Int. Cl. H01L 23/58; H01L 21/68

(52) U.S. Cl. 257/48; 438/16; 257/E23.179; 257/E21.53

(57) ABSTRACT

A method of measuring thickness of a layer in an image sensor and pattern for the same are disclosed, by which layer thickness measurement of an image sensor is enabled in the course of fabrication. Embodiments relate to a method of measuring thickness of a layer in an image sensor in which a first epitaxial layer may be formed over a semiconductor substrate. A photoresist pattern may be formed by coating and patterning photoresist over the first epitaxial layer. A plurality of trenches in the first epitaxial layer may be formed by performing a dry etch on the photoresist pattern. A doped layer may be formed at a bottom of each of the trenches by implanting antimony (Sb) using the photoresist pattern as a mask. After removing the photoresist pattern, a second epitaxial layer may be formed over the first epitaxial layer including a plurality of the trenches. The thickness of the second epitaxial layer may be measured to determine the thickness of one of the doped layers.

The present application claims priority under 35 U.S.C. 119 to Korean Patent Application No. 10-2006-0117374, filed on Nov. 27, 2006, which is hereby incorporated by reference in its entirety.

### BACKGROUND

To measure layer thickness in a semiconductor device field including a CMOS image sensor, mid-infrared reflective spectroscopy using FT-IR (Fourier Transform Infrared) Spectroscopy may be used. In this process, a spectrum reflected on a layer of a semiconductor device may be measured using an IR spectroscope. An interference stripe pattern in the spectrum is then interpreted.

The FT-IR spectroscopy determines a thickness through a relatively simple interpretation of an interference stripe pattern when a layer over the substrate is a single layer. For instance, a thickness of a single layer can be found by measuring a reflection of an incident light at an interface between a substrate and a corresponding layer and an interference stripe pattern of a reflective spectrum of an incident light at a semiconductor substrate surface.

In particular, a semiconductor substrate may have a high carrier concentration of 10¹⁸ to about 10¹⁹ cm³. A carrier concentration of an epitaxial layer, for example, is lower than that of the substrate. An incident IR ray will be transmitted through an epitaxial layer of low concentration, and reflected at the interface between the epitaxial layer and a substrate. The ray then interferes with light reflected from a surface of the substrate to generate an interference stripe pattern in a reflective spectrum.

The interference stripe pattern is attributed to an optical path difference between light reflected from an epitaxial layer/substrate interface and light reflected from the wafer surface. A thickness of the epitaxial layer may be measured based on the period of the interference strip pattern, which is inversely proportional to a thickness of the epitaxial layer.

However, it is impossible to measure a thickness of an epitaxial layer on a semiconductor substrate in an actual process. So, thickness measurement of an epitaxial layer may be carried out using a separate semiconductor substrate. Due to the technical limit of the FT-IR spectroscopy for layer thickness measurement, thickness can be measured only if the difference of the dopant concentration between a lower layer and a layer to be measured is at least about 2.0×10¹⁵ atoms/cm³.

Since the dopant difference between the lower layer and the grown epitaxial layer is nearly non-existent in a related art process, it is impossible to perform thickness measurement on a semiconductor substrate in an actual process.

### SUMMARY

Embodiments relate to a method of measuring thickness of a layer in an image sensor and pattern for the same. Embodiments relate to a method of measuring thickness of a layer in an image sensor which is enabled in the course of fabrication. Embodiments relate to a pattern for measuring thickness of a layer in an image sensor which is enabled in the course of fabrication. Embodiments relate to a method of measuring thickness of a layer in an image sensor and pattern for the same, by which thickness of each layer in a CMOS image sensor can be directly measured.

Embodiments relate to a method of measuring thickness of a layer in an image sensor in which a first epitaxial layer may be formed over a semiconductor substrate. A photoresist pattern may be formed by coating and patterning photoresist over the first epitaxial layer. A plurality of trenches in the first epitaxial layer may be formed by performing a dry etch on the photoresist pattern. A doped layer may be formed at a bottom of each of the trenches by implanting antimony (Sb) using the photoresist pattern as a mask. After removing the photoresist pattern, a second epitaxial layer may be formed over the first epitaxial layer including a plurality of the trenches. The thickness of the second epitaxial layer may be measured to determine the thickness of one of the doped layers.

Embodiments relate to a pattern for measuring thickness of a layer in an image sensor which includes a semiconductor substrate and a first epitaxial layer over the semiconductor substrate. A plurality of trenches are provided in the first epitaxial layer. A plurality of doped layers are provided in the bottoms of a plurality of the trenches, and a second epitaxial layer is provided over the first epitaxial layer.

A plurality of the doped layers may be formed by implanting Sb at a dose of about 2.0×10¹⁵ to about 10¹⁹ atoms. A plurality of the trenches may be provided to one or both sides of a single shot area. A plurality of the trenches may include a first trench as an align mark and a second trench for thickness measurement. The second trench may be configured to have a curved shape.

### DRAWINGS

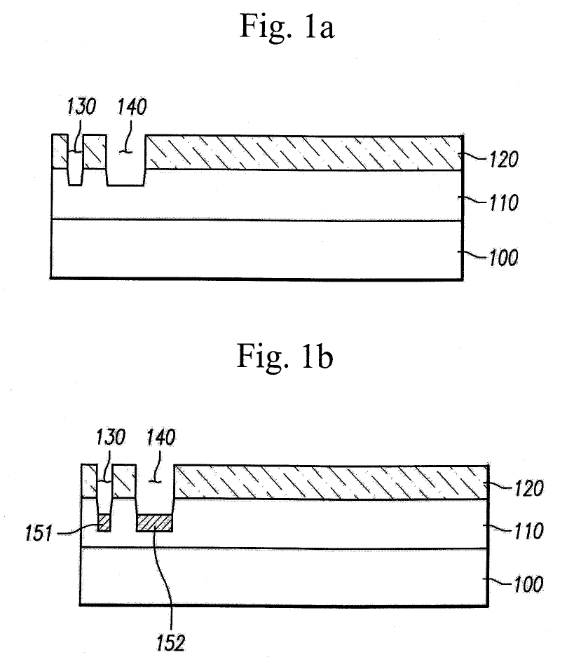

Example FIGS. 1A to 1C are cross-sectional diagrams for a method of measuring layer thickness for a thickness measurement pattern in an image sensor according to embodiments.

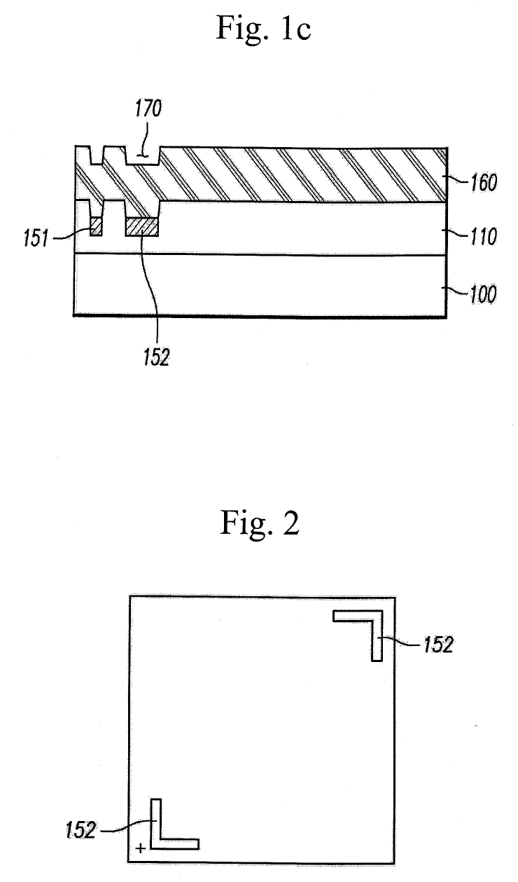

Example FIG. 2 is a layout of a thickness measurement pattern of an image sensor according to embodiments.

### DESCRIPTION

A method of measuring thickness of a layer in an image sensor and pattern for the same, which enable measurement during the fabricating process are explained in detail with reference to example FIGS. 1A to 1C as follows. Example FIGS. 1A to 1C are cross-sectional diagrams for a method of measuring layer thickness using a thickness measurement pattern in an image sensor according to embodiments.

Referring to example FIG. 1A, to measure layer thickness of an image sensor in the course of fabricating the image sensor, a first epitaxial layer 110 to be provided with a photodiode is formed over a semiconductor substrate 100 by epitaxial growth. The epitaxial growth includes one of vacuum deposition carried out while a substrate is heated at high temperature, MPE (molecular beam epitaxy), and VPE (vapor phase epitaxy), for example. The first epitaxial layer 110 may be formed at approximately 1,000˜1,200° C. and at about atmospheric pressure (760 torr) or reduced pressure (20 torr or below).

Subsequently, photoresist is coated over the first epitaxial layer 110 and then defined to form a photoresist pattern 120.

The photoresist pattern 120 is dry-etched to form a first trench 130 as an alignment mark and a second trench 140 for thickness measurement in the first epitaxial layer 110.

Referring to example FIG. 1B, after the first and second trenches 130 and 140 have been formed, Sb is implanted at a dose of approximately 2.0×10¹⁵ to 10¹⁹ atoms without removing the photoresist pattern 120. So, a first doped layer 151 and a second doped layer 152 are formed within the first and second trenches 130 and 140, respectively.

Referring to example FIG. 1C, after the photoresist pattern 120 has been removed, a second epitaxial layer 160 is formed. For instance, the second epitaxial layer 160 is formed of the same material as the first epitaxial layer 110. Like the first epitaxial layer 110, the second epitaxial layer 160 may be provided within a plurality of photodiodes for sensing incident light inside.

As the second epitaxial layer 160 is formed, a plurality of recesses 170, may be formed over a whole surface of the substrate, i.e., an upper surface of the second epitaxial layer 160. The recesses have depths approximately equal to the depths of a plurality of the trenches 130 and 140 provided to the first epitaxial layer 110, minus the thickness of the doped layers 151 and 152. The recesses 170 may be used as a thickness measurement area.

In this case, the first trench 130 provided with the first doped layer 151 plays a role as an alignment mark for estimating a size of one shot and enabling DM (defect monitoring). The second doped layer 152 plays a role as a reflective layer for measuring a thickness of the second epitaxial layer 160 using FT-IR.

The above-configured second doped layer 152, as shown in example FIG. 2, can be provided to one side or both sides of a single shot area of the semiconductor substrate. While the second doped layer 152 is provided to one or both sides of the single shot area, if infrared is applied by FT-IR (Fourier Transform Infrared) spectroscopy through the thickness measurement area of the second epitaxial layer 160, the dopant difference between the second doped layer 152 and the second epitaxial layer 160 is at least approximately 2.0×10¹⁵ atoms. Constructive or destructive interference causes reflected light signals to vary according to the thickness of the second epitaxial layer 160. By analyzing the variations in the detected data, the thickness of the second epitaxial layer 160 may be measured. Each of the first and second epitaxial layers may be formed of TCS (SiHCl₃).

The first trench 130 provided with the first doped layer 151 is indicated by a mark ‘+’ in example FIG. 2. The second doped layer 152 may be provided in a bent shape to one or both sides of the shot area.

An estimate how large a size of a single shot may therefore be made when a semiconductor substrate is aligned using detection equipment. Tests for important surface characteristics which are important to the semiconductor device characteristics, i.e., DM (defect monitoring), may be performed.

Accordingly, embodiments do not require the measurement of an epitaxial layer thickness using a separate dummy semiconductor substrate. Embodiments may thus reduce errors generated from inferring the real layer thickness from data measured using the dummy substrate. Embodiments may therefore enable defect monitoring of a surface of an epitaxial layer, thereby enhancing performance in an image sensor.

Embodiments do not need a separate dummy semiconductor substrate to measure a thickness of an epitaxial layer but enable thickness measurement on a real semiconductor substrate. Embodiments can reduce errors generated from estimating thickness of a real layer using data measured via a dummy substrate

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a first epitaxial layer over a semiconductor substrate;
forming a plurality of trenches in the first epitaxial layer by performing a dry etch on the photoresist pattern;
forming a doped layer at a bottom of each of the trenches by implanting antimony;
forming a second epitaxial layer over the first epitaxial layer including a plurality of the trenches; and
measuring thickness of the second epitaxial layer for one of the doped layers.

2. The method of claim 1, wherein said forming a plurality of trenches in the first epitaxial layer comprises forming a photoresist pattern by coating and patterning photoresist over the first epitaxial layer, and performing a dry etch on the photoresist pattern.

3. The method of claim 2, wherein said forming a doped layer at a bottom of each of the trenches uses the photoresist pattern as a mask.

4. The method of claim 2, wherein said forming a second epitaxial layer is performed after removing the photoresist pattern.

5. The method of claim 1, wherein said measuring thickness of the second epitaxial layer for one of the doped layers comprises measuring thickness of a layer in an image sensor.

6. The method of claim 1, wherein each of the first and second epitaxial layers are formed of SiHCl₃.

7. The method of claim 1, wherein each of the first and second epitaxial layers is grown by one selected from the group consisting of high temperature vacuum deposition, molecular beam epitaxy, and vapor phase epitaxy.

8. The method of claim 1, wherein a plurality of the trenches comprise a first trench as an align mark and a second trench for thickness measurement.

9. The method of claim 8, wherein the second trench is configured to have a bent shape.

10. The method of claim 1, wherein the antimony is implanted at a dose between approximately 2×10¹⁵ atoms and approximately 10×10¹⁹ atoms.

11. The method of claim 1, wherein a plurality of the trenches are provided to one or both sides of a single shot area.

12. The method of claim 1, wherein the second epitaxial layer thickness measuring step comprising the step of measuring the thickness of the second epitaxial layer by Fourier Transform Infrared Spectroscopy.

13. An apparatus comprising:
a semiconductor substrate;
a first epitaxial layer over the semiconductor substrate;
a plurality of trenches in the first epitaxial layer;
a plurality of doped layers formed in the bottoms of a plurality of the trenches, respectively; and
a second epitaxial layer over the first epitaxial layer.

14. The apparatus of claim 13, wherein said plurality of the doped layers are formed by implanting antimony at a dose between approximately 2×10¹⁵ atoms and approximately 10×10¹⁹ atoms.

15. The apparatus of claim 13, wherein a plurality of said trenches are provided to one side of a single shot area.

16. The apparatus of claim 13, wherein said plurality of trenches comprises a first trench as an alignment mark.

17. The apparatus of claim 16, wherein said plurality of trenches comprises a second trench for thickness measurement.

18. The apparatus of claim 17, wherein the second trench is configured to have a bent shape.

19. The apparatus of claim 13, wherein the apparatus is a pattern for measuring thickness of a layer in an image sensor.

20. The apparatus of claim 13, wherein a plurality of said trenches are provided to both sides of a single shot area.
